(19) United States
(12) Patent Application Publication
(10) Pub. No.: US 2009/0045453 A1
(43) Pub. Date: Feb. 19, 2009

(54) NONVOLATILE MEMORY DEVICES INCLUDING GATE CONDUCTIVE LAYERS HAVING PEROVSKITE STRUCTURE AND METHODS OF FABRICATING THE SAME

(75) Inventor: Jang-eun Heo, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/109,669

(22) Filed: Apr. 25, 2008

(30) Foreign Application Priority Data
Aug. 16, 2007 (KR) 10-2007-0082352

(51) Int. Cl. H01L 29/792; H01L 21/4763

(52) U.S. Cl. 257/324; 438/591; 257/E21.679; 257/E29.309

(57) ABSTRACT

A nonvolatile memory device includes a tunneling insulating layer on a semiconductor layer. A charge storage layer is on the tunneling insulating layer. A blocking insulating layer having a Perovskite structure is on the charge storage layer. A gate conductive layer having a Perovskite structure is on the blocking insulating layer.

### CROSS-REFERENCE TO RELATED PATENT APPLICATION

This application claims the benefit of Korean Patent Application No. 10-2007-0082352, filed on Aug. 16, 2007, in the Korean Intellectual Property Office, the disclosure of which is incorporated herein in its entirety by reference.

### BACKGROUND

The present invention relates to semiconductor memory devices, and more particularly, to nonvolatile memory devices including gate conductive layers.

Semiconductor memory devices that store data may be generally classified into volatile memory devices and nonvolatile memory devices. Volatile memory devices lose data in the event of power interruption, while nonvolatile memory devices retain stored data even if power is abruptly interrupted.

Nonvolatile memory devices include an electrically erasable programmable read-only memory (EEPROM) that is capable of electrically writing and erasing data. A unit cell of the EEPROM may include a stacked gate structure in which a tunneling insulating layer, a charge storage layer, a blocking insulating layer, and a gate electrode are stacked sequentially. In an EEPROM, a relatively high voltage is generally used to program or erase data, which can result in large power consumption.

### SUMMARY

A nonvolatile memory device according to some embodiments includes a tunneling insulating layer disposed on a semiconductor layer. A charge storage layer is on the tunneling insulating layer. A blocking insulating layer having a Perovskite structure is on the charge storage layer. A gate conductive layer having a Perovskite structure is on the blocking insulating layer.

A hydrogen diffusion blocking spacer may be provided on a sidewall of the gate conductive layer. The hydrogen diffusion blocking spacer may extend onto a sidewall of the blocking insulating layer. The hydrogen diffusion blocking spacer may be on the charge storage layer. The hydrogen diffusion blocking spacer may include aluminium oxide, silicon nitride, and/or silicon oxide. Also, the hydrogen diffusion blocking spacer may include a single layer of an aluminum oxide layer, a double layer of an aluminum oxide layer and a silicon nitride layer, and/or a double layer of a silicon nitride layer and a silicon oxide layer.

A barrier conductive layer may be disposed on the gate conductive layer. The barrier conductive layer may include TiN, WN, TaN, TiSiN, WSiN, and/or TaSiN. A word line conductive layer may be disposed on and electrically connected to the barrier conductive layer.

The gate conductive layer may include CaRuO₃, (Ba,Sr)RuO₃, SrRuO₃, SrlrO₃, LaNiO₃, and/or (La,Sr)MnO₃. In some embodiments, the gate conductive layer may include a material having a larger work function than polysilicon (poly-Si).

The blocking insulating layer may include LaMnO₃, LaAlO₃, MgSiO₃, (Ca,Na)(Nb,Ti,Fe)O₃, (Ce,Na,Ca)₂(Ti,Nb)₂O₆, NaNbO₃, SrTiO₃, (Na,La,Ca)(Nb,Ti)O₃, Ca₃(Ti,Al,Zr)₉O₂₀, PbTiO₃, (Ca,Sr)TiO₃, CaTiO₃, Pb(Zr,Ti)O₃, (Ba,Sr)TiO₃, BaTiO₃, KTaO₃, (Bi,La)FeO₃ and/or Ba(Fe_{1/2}Nb_{1/2})O₃.

Methods of fabricating a nonvolatile memory device according to some embodiments include forming a tunneling insulating layer on a semiconductor layer, forming a charge storage layer on the tunneling insulating layer, forming a blocking insulating layer having a Perovskite structure on the charge storage layer, and forming a gate conductive layer having a Perovskite structure on the blocking insulating layer.

The methods may further include patterning the gate conductive layer, and forming a hydrogen diffusion blocking spacer on a sidewall of the patterned gate conductive layer.

The methods may further include patterning the blocking insulating layer after the patterning of the gate conductive layer, wherein the hydrogen diffusion blocking spacer is also formed also on a sidewall of the blocking insulating layer.

The hydrogen diffusion blocking spacer may include aluminium oxide, silicon nitride, and/or silicon oxide.

The hydrogen diffusion blocking spacer may include a single layer of an aluminum oxide layer, a double layer of an aluminum oxide layer and a silicon nitride layer, and/or a double layer of a silicon nitride layer and a silicon oxide layer.

The methods may further include forming a barrier conductive layer on the gate conductive layer.

The barrier conductive layer may include TiN, WN, TaN, TiSiN, WSiN, and/or TaSiN.

The methods may further include forming a word line conductive layer on the barrier conductive layer.

The gate conductive layer may include CaRuO₃, (Ba,Sr)RuO₃, SrRuO₃, SrlrO₃, LaNiO₃, and/or (La,Sr)MnO₃. In some embodiments, the gate conductive layer may include a material having a larger work function than poly-Si. In particular embodiments, the gate conductive layer may include SrRuO₃.

The blocking insulating layer may include LaMnO₃, LaAlO₃, MgSiO₃, (Ca,Na)(Nb,Ti,Fe)O₃, (Ce,Na,Ca)₂(Ti,Nb)₂O₆, NaNbO₃, SrTiO₃, (Na,La,Ca)(Nb,Ti)O₃, Ca₃(Ti,Al,Zr)₉O₂₀, PbTiO₃, (Ca,Sr)TiO₃, CaTiO₃, Pb(Zr,Ti)O₃, (Ba,Sr)TiO₃, BaTiO₃, KTaO₃, (Bi,La)FeO₃ and/or Ba(Fe_{1/2}Nb_{1/2})O₃.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a block diagram of a nonvolatile memory device according to some embodiments;

FIG. 2 illustrates the layout (plan view) of a portion of a memory cell array of a nonvolatile memory device according to some embodiments;

FIGS. 3A and 3B are cross-sectional views taken along lines I-I′ and II-II′ of FIG. 2, respectively;

FIG. 4 illustrates the layout (plan view) of a portion of a memory cell array of a nonvolatile memory device according to some embodiments;

FIG. 5 is a cross-sectional view taken along a line V-V′ of FIG. 4;

FIGS. 6A through 6C are cross-sectional views illustrating methods of fabricating a nonvolatile memory device according to some embodiments;

FIGS. 7A through 7B are cross-sectional views illustrating methods of fabricating a nonvolatile memory device according to some embodiments; and

FIG. 8 is a schematic diagram of a system including a nonvolatile memory device according to some embodiments.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

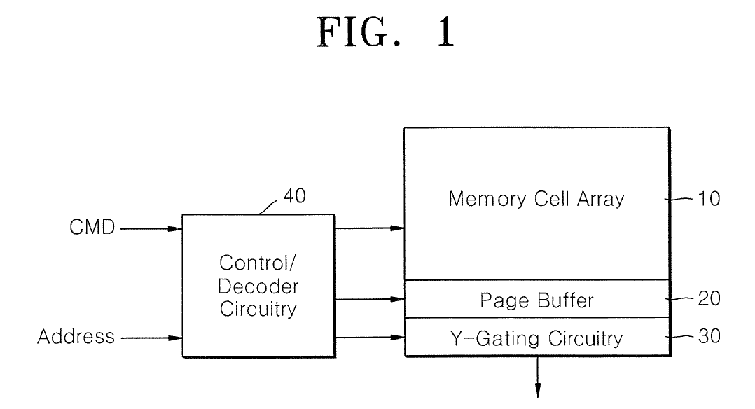

FIG. 1 is a block diagram of a nonvolatile memory device according to some embodiments. Referring to FIG. 1, the nonvolatile memory device may include a memory cell array 10, a page buffer 20, a Y-gating circuit 30, and a control/decoder circuit 40.

The memory cell array 10 may include a plurality of memory blocks, each of which may include a plurality of nonvolatile memory cells. The nonvolatile memory cells may be flash memory cells, specifically, NAND flash memory cells. The page buffer 20 may temporarily store data to be written to the memory cell array 10 or data to be read from the memory cell array 10. The Y-gating circuit 30 may transmit data stored in the page buffer 20. The control/decoder circuit 40 may externally receive a command CMD and an address, output a control signal for writing data to the memory cell array 10 or reading data from the memory cell array 10, and decode the address. The control/decoder circuit 40 may output a control signal for inputting and outputting data to the page buffer 20 and provide address information to the Y-gating circuit 30.

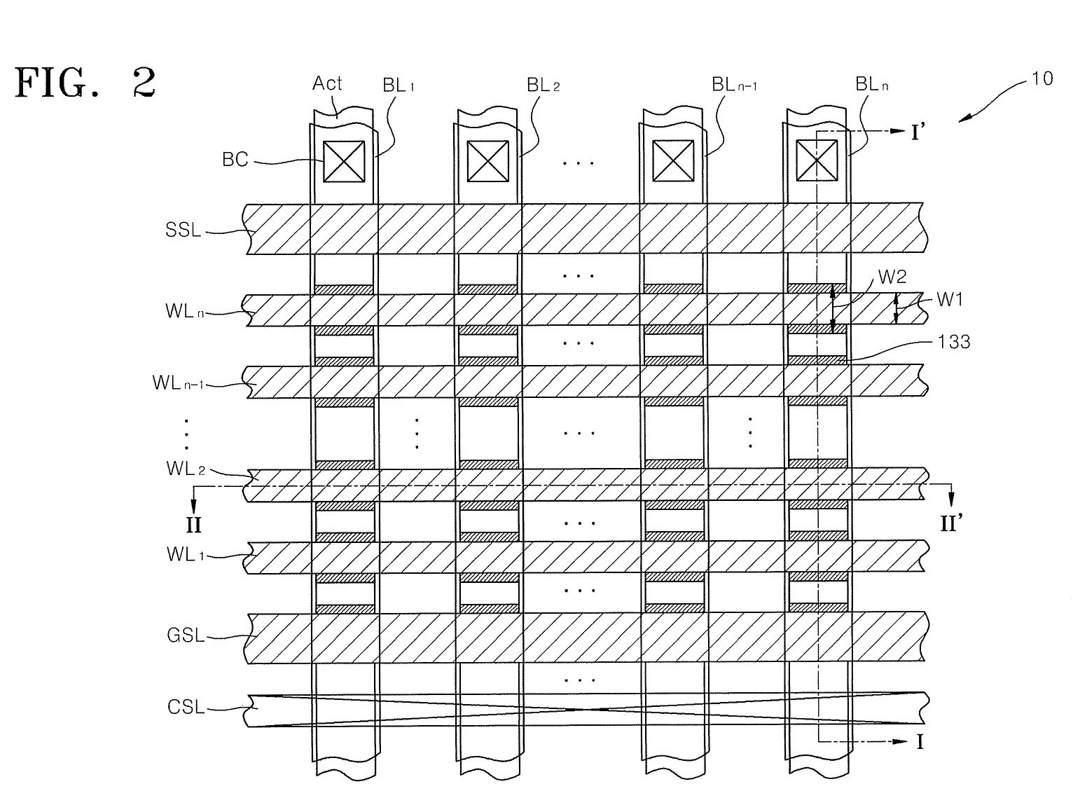

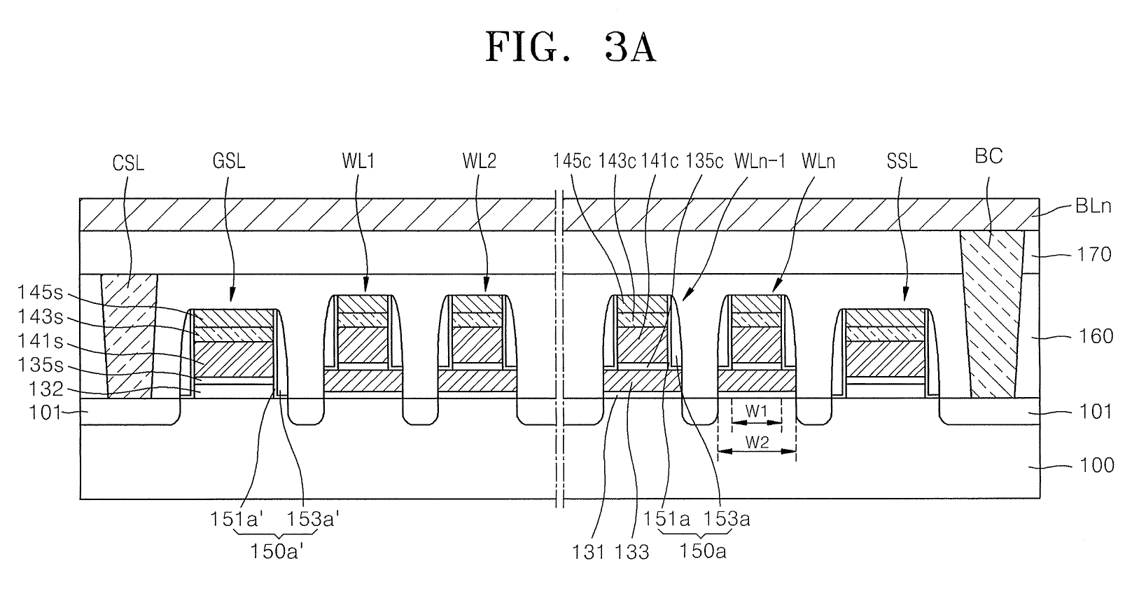

FIG. 2 illustrates the layout of a portion of a memory cell array according to some embodiments. The portion of the memory cell array shown in FIG. 2 may be a portion of the memory cell array 10 in FIG. 1. FIGS. 3A and 3B are cross-sectional views taken along lines I-I′ and II-II′ of FIG. 2, respectively.

Referring to FIGS. 2 and 3A and 3B, the memory cell array 10 may include a plurality of active regions Act that are defined by device isolation regions 100a formed in a semiconductor layer 100. The semiconductor layer 100 can include a substrate and/or an epitaxial layer, a silicon on insulator layer, or the like. The active regions Act may be provided in the shape of parallel lines.

A string selection line SSL and a ground selection line GSL may run across and over the active regions Act. A plurality of word lines WL1, WL2, . . . , WLn−1, and WLn may run across and over the active regions Act between the string selection line SSL and the ground selection line GSL. The string selection line SSL, the ground selection line GSL, and the word lines WL1, WL2, . . . , WLn−1, and WLn may be parallel to one another. Impurity regions 101 may be formed in the active regions Act adjacent to both sides of each of the word lines WL1, WL2, . . . , WLn−1, and WLn, the string selection line SSL, and the ground selection line GSL. As a result, a string selection transistor, cell transistors, and a ground selection transistor that are connected in series are formed. The string selection transistor, the ground selection transistor, and the cell transistors interposed therebetween may constitute a unit memory block. The impurity region 101 disposed adjacent to the string selection line SSL and opposite to the ground selection line GSL may be defined as a drain region of the string selection transistor. Also, the impurity region 101 disposed adjacent to the ground selection line GSL and opposite to the string selection line SSL may be defined as a source region of the ground selection transistor.

Each of the word lines WL1, WL2, . . . , WLn−1, and WLn may include a cell gate conductive layer 141c, a cell barrier conductive layer 143c, and a word line conductive layer 145c that are stacked sequentially. However, the present invention is not limited thereto. For example, the word line conductive layer 145c may be omitted. Further, the cell barrier conductive layer 143c may be also omitted. A tunneling insulating layer 131, a charge storage layer 133, and a blocking insulating layer 135c may be stacked sequentially between the cell gate conductive layer 141c and the semiconductor layer 100.

Each of the tunneling insulating layer 131 and the charge storage layer 133 may be separated into portions with respect to the cell transistors disposed adjacently in the direction of the word lines WL1, WL2, . . . , WLn−1, and WLn. Top surfaces of the device isolation regions 100a may be at substantially the same level as a top surface of the charge storage layer 133. The tunneling insulating layer 131 may be a silicon oxide layer. The charge storage layer 133 may be a charge trapping layer or a floating gate conductive layer. The blocking insulating layer 135c may be shared among the cell transistors disposed adjacently in the direction of the word lines WL1, WL2, . . . , WLn−1, and WLn. A width W1 of the cell gate conductive layer 141c may be smaller than a width W2 of the charge storage layer 133. Each of the blocking insulating layer 135c, the cell barrier conductive layer 143c, and the word line conductive layer 145c may have substantially the same width as the width W1 of the cell gate conductive layer 141c. As such, the top surface of the charge storage layer 133 may be exposed on both sides of the blocking insulating layer 135c.

The blocking insulating layer 135c may include a material having a higher dielectric constant than the tunneling insulating layer 131, for example, a high-k dielectric material. Specifically, the blocking insulating layer 135c may include a high-k dielectric material with a Perovskite structure. The cell gate conductive layer 141c may be a conductive layer with a Perovskite structure. By forming the cell gate conductive layer 141c with the same Perovskite structure as the blocking insulating layer 135c on the blocking insulating layer 135c, lattice mismatch between the blocking insulating layer 135c and the cell gate conductive layer 141c can be reduced. The cell gate conductive layer 141c with the Perovskite structure may include a material having a larger work function than polysilicon (poly-Si). In this case, a conductive band offset (i.e., a potential barrier to electrons) between the cell gate conductive layer 141c and the blocking insulating layer 135c is increased, compared with a case where the cell gate conductive layer 141c is a poly-Si layer. Accordingly, back tunneling of electrons to the charge storage layer 133 through the blocking insulating layer 135c during a data erase operation can be reduced, thereby improving data erase speed.

A first hydrogen diffusion blocking spacer 150a may be disposed on the exposed top surface of the charge storage layer 133 and on a sidewall of the cell gate conductive layer 141c. The first hydrogen diffusion blocking spacer 150a may extend onto a sidewall of the blocking insulating layer 135c. As a result, sidewalls of the cell gate conductive layer 141c and the blocking insulating layer 135 with the Perovskite structures may be enclosed by the first hydrogen diffusion blocking spacer 150a. In this case, a sidewall of the charge storage layer 133 may be aligned with an outer sidewall of the first hydrogen diffusion blocking spacer 150a. The first hydrogen diffusion blocking spacer 150a may include a first L-shaped lower spacer 151a and a first upper spacer 153a disposed on the first L-shaped lower spacer 51a.

The cell barrier conductive layer 143c may be a conductive layer that can reduce/prevent diffusion of hydrogen therethrough. When the cell barrier conductive layer 143c is formed, the first hydrogen diffusion blocking spacer 150a may extend onto a sidewall of the cell barrier conductive layer 143c. The cell gate conductive layer 141c and the blocking insulating layer 135c with the Perovskite structures may be encapsulated by the first hydrogen diffusion blocking spacer 150a and the cell barrier conductive layer 143c.

Each of the string selection line SSL and the ground selection line GSL may include a selection gate conductive layer 141s, a selection barrier conductive layer 143s, and a selection line conductive layer 145s that are stacked sequentially. However, the present invention is not limited thereto. For example, the selection line conductive layer 145s may be omitted. Further, the selection barrier conductive layer 143s may be also omitted. A selection gate insulating layer 132 may be disposed between the selection gate conductive layer 141s and the semiconductor layer 100. The selection gate insulating layer 132 may be a silicon oxide layer. Also, the selection gate insulating layer 132 may be thicker than the tunneling insulating layer 131. A high-k dielectric layer 135s with a Perovskite structure may be disposed between the selection gate conductive layer 141s and the selection gate insulating layer 132. The high-k dielectric layer 135s can be formed using the same process as the blocking insulating layer 135c. The selection gate conductive layer 141s may be a conductive layer with a Perovskite structure, which is formed using the same process as the cell gate conductive layer 141c.

A second hydrogen diffusion blocking spacer 150a′ may be disposed on a sidewall of the selection gate conductive layer 141s. The second hydrogen diffusion blocking spacer 150a′ may extend onto sidewalls of the high-k dielectric layer 135s and the selection gate insulating layer 132. The selection barrier conductive layer 143s may be a conductive layer, which is formed using the same process as the cell barrier conductive layer 143c and can reduce/prevent diffusion of hydrogen. When the selection barrier conductive layer 143s is formed, the second hydrogen diffusion blocking spacer 150a′ may extend onto a sidewall of the selection barrier conductive layer 143s. The selection gate conductive layer 141s and high-k dielectric layer 135s with the Perovskite structures may be encapsulated by the second hydrogen diffusion blocking spacer 150a′ and the selection barrier conductive layer 143s. The second hydrogen diffusion blocking spacer 150a′ may include a second L-shaped lower spacer 151a′ and a second upper spacer 153a′ disposed on the second L-shaped lower spacer 151a′.

A first interlayer insulating layer 160 is provided on the word lines WL1, WL2, . . . , WLn−1, and WLn and the selection lines SSL and GSL. A common source line CSL is disposed through the first interlayer insulating layer 160 and connected to the source region of the ground selection line GSL. The common source line CSL may be disposed parallel to the ground selection line GSL.

A second interlayer insulating layer 170 may be provided on the first interlayer insulating layer 160. A bit line plug BC may be disposed through the second interlayer insulating layer 170 and the first interlayer insulating layer 160 and connected to the drain region of the string selection line SSL. Bit lines BL1, BL2, BLn−1, and BLn may be disposed on the second interlayer insulating layer 170 and connected to the bit line plug BC. Also, the bit lines BL1, BL2, . . . , BLn−1, and BLn run across and over the word lines WL1, WL2, . . . , WLn−1, and WLn. The bit lines BL1, BL2, . . . , BLn−1, and BLn may be disposed parallel to the active regions Act.

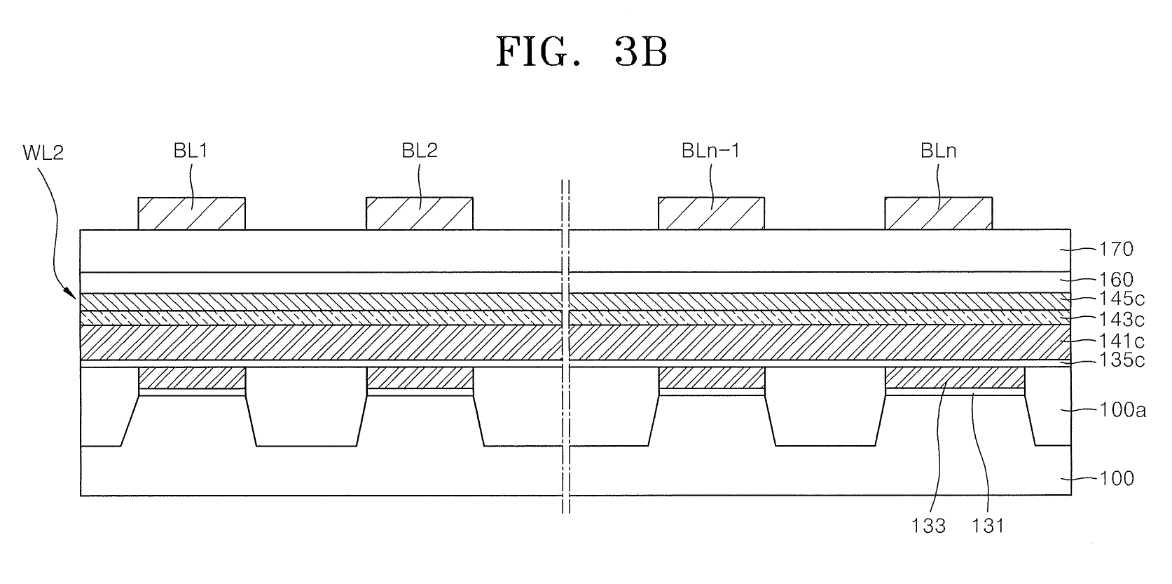

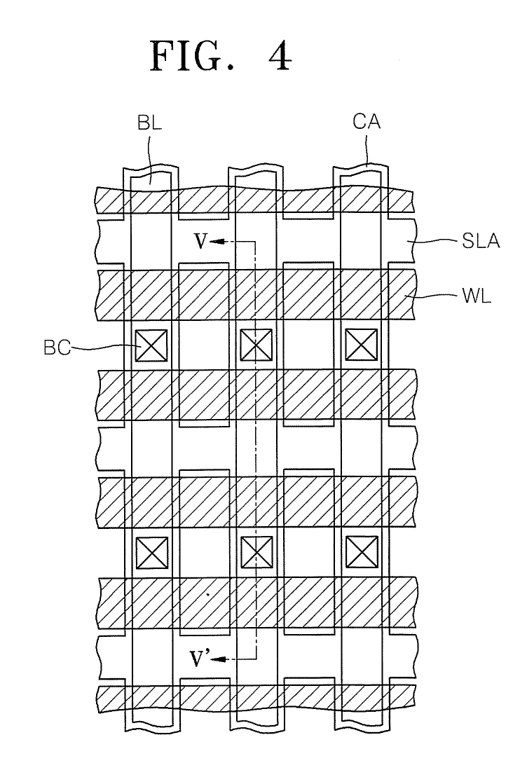

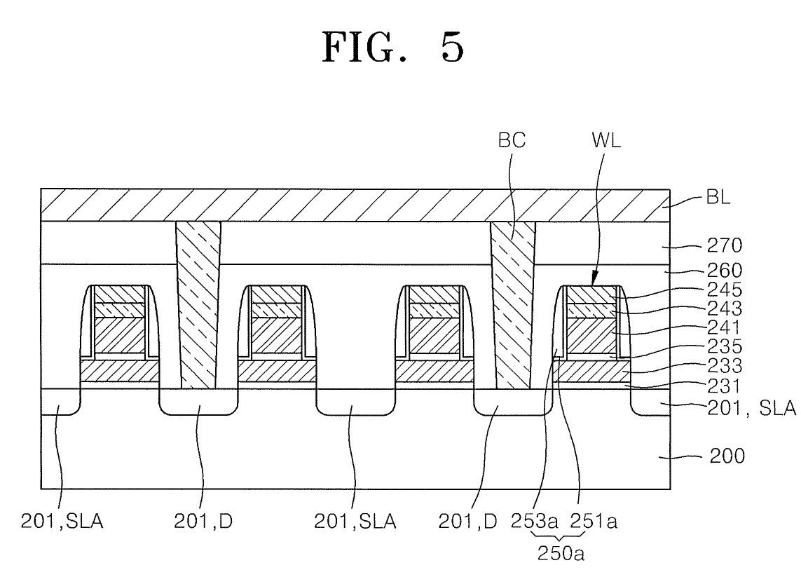

FIG. 4 illustrates the layout of a portion of a memory cell array of a nonvolatile memory device 10 according to some embodiments. In the embodiments illustrated in FIG. 4, the memory cell array may be a NOR flash memory. FIG. 5 is a cross-sectional view taken along a line V-V′ of FIG. 4.

Referring to FIGS. 4 and 5, an active region is defined by a device isolation layer formed in a semiconductor layer 100. The active region includes a plurality of parallel common source line active regions SLA and a plurality of cell active regions CA disposed across the common source line active regions SLA.

A pair of word lines WL are disposed over each of the cell active regions CA and spaced apart from one another. The word lines WL are disposed adjacent to the common source line active regions SLA, respectively. Impurity regions 201 are formed in the cell active region CA and the common source line active region SLA that are exposed between the pair of word lines WL. As a result, a pair of cell transistors may be defined on each of the cell active regions CA. The impurity region 201 formed in the cell active region CA may be defined as a drain region D, while the impurity region 201 formed in the common source line active region SLA may be defined as a common source region CS.

Each of the word lines WL may include a gate conductive layer 241, a barrier conductive layer 243, and a word line conductive layer 245 that are stacked sequentially. However, the present invention is not limited thereto. For example, the word line conductive layer 245 may be omitted. Further, the barrier conductive layer 243 may be also omitted. A tunneling insulating layer 231, a charge storage layer 233, a blocking insulating layer 235 may be stacked sequentially between the gate conductive layer 241 and the semiconductor layer 100. The tunneling insulating layer 231, the charge storage layer 233, the blocking insulating layer 235, the gate conductive layer 241, the barrier conductive layer 243, and the word line conductive layer 245 may be formed in a similar manner as the tunneling insulating layer 131, the charge storage layer 133, the blocking insulating layer 135c, the cell gate conductive layer 141c, the cell barrier conductive layer 143c, and the word line conductive layer 145c, respectively, which are described above with reference to FIGS. 2, 3A, and 3B.

A hydrogen diffusion blocking spacer 250a may be disposed on a sidewall of the gate conductive layer 241. The hydrogen diffusion blocking spacer 250a may extend onto sidewalls of the blocking insulating layer 235c, the barrier conductive layer 243, and the word line conductive layer 245. The hydrogen diffusion blocking spacer 250a may include an L-shaped lower spacer 251a and an upper spacer 253a disposed on the L-shaped lower spacer 251a.

An interlayer insulating layer 260 may be provided on the word lines WL. A bit line plug BC may be disposed through the interlayer insulating layer 260 and connected to the drain region D. Bit lines BL may be disposed on the interlayer insulating layer 260 and connected to the bit line plug BC. The bit lines BL may run across and over the word lines WL. The bit lines BL may be disposed parallel to the cell active regions CA.

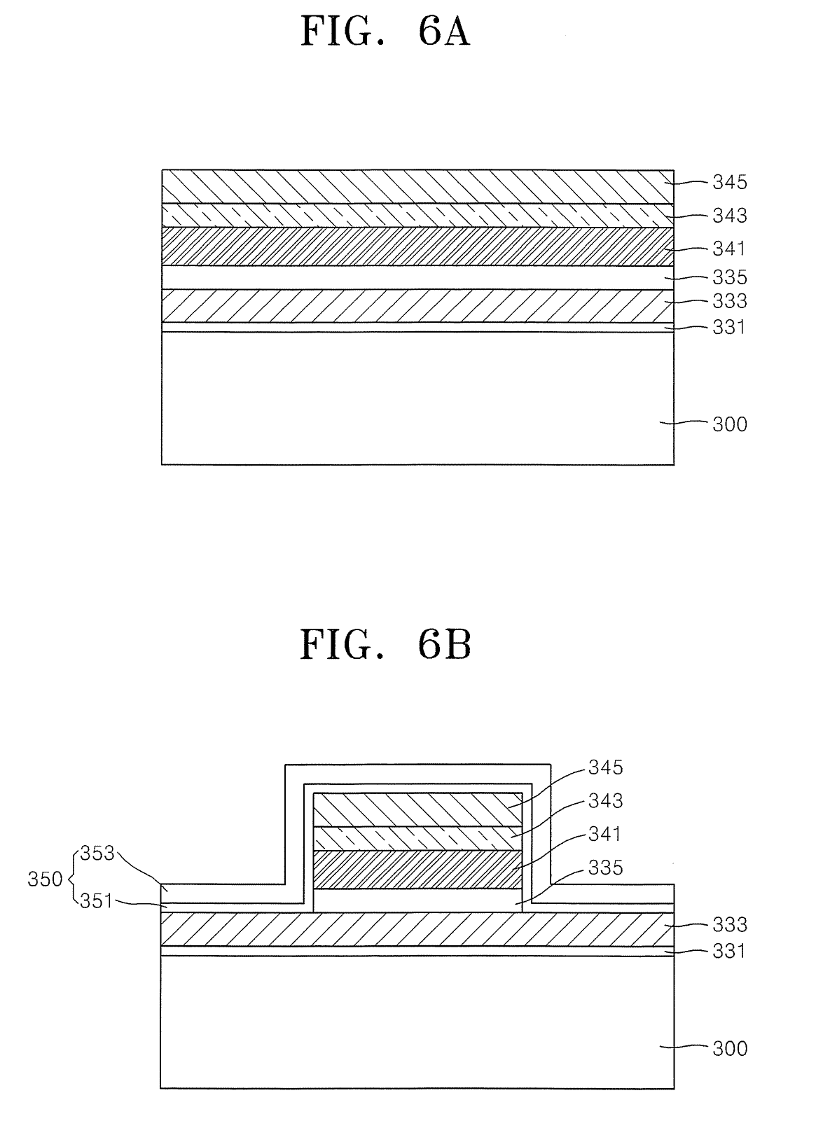

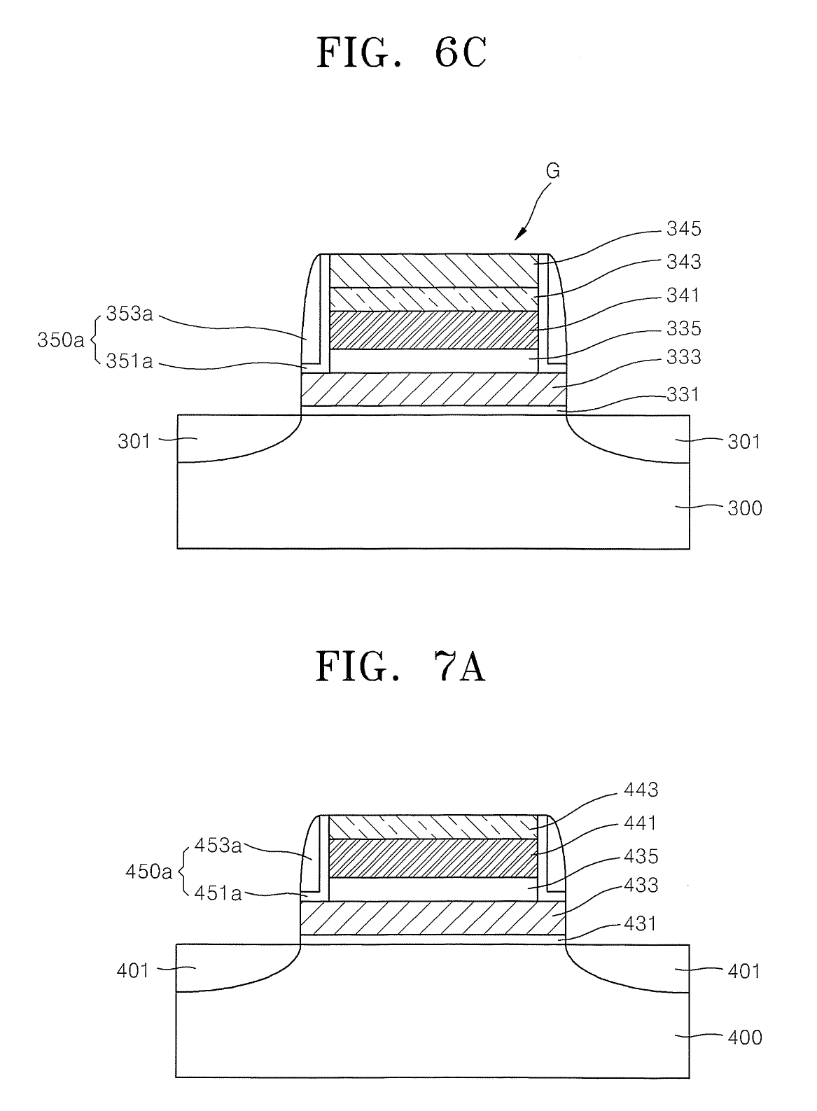

FIGS. 6A through 6C are cross-sectional views illustrating methods of fabricating a nonvolatile memory device according to some embodiments. Specifically, FIGS. 6A through 6C illustrate methods of fabricating the cell transistors described above with reference to FIGS. 2 and 3A and 3B or FIGS. 4 and 5.

Referring to FIG. 6A, a tunneling insulating layer 331 may be stacked on a substrate 300. The substrate 300 may be a silicon substrate. The tunneling insulating layer 331 may be a silicon oxide layer. Specifically, the tunneling insulating layer 331 may be a thermal oxide layer with a thickness of about 20 to 100 Å.

A charge storage layer 333 may be stacked on the tunneling insulating layer 331. The charge storage layer 333 may be a charge trapping layer and/or a floating gate conductive layer. The charge trapping layer may be a silicon nitride layer, a silicon oxynitride layer, and/or an insulating layer containing conductive nanocrystals, for example. The floating gate conductive layer may be a poly-Si layer. The charge storage layer 333 may be formed to a thickness of about 20 to 150 Å.

A blocking insulating layer 335 may be stacked on the charge storage layer 333. The blocking insulating layer 335 may include a material having a higher dielectric constant than the tunneling insulating layer 331, for example high-k dielectric material. The blocking insulating layer 335 may include a high-k dielectric material with a Perovskite structure. In this case, an electric field applied to the tunneling insulating layer 331 may be stronger than an electric field applied to the blocking insulating layer 335. As a result, injection of electrons into the charge storage layer 333 through the tunneling insulating layer 331 may be facilitated during a data program operation, thereby improving data program speed. Also, emission of electrons from the charge storage layer 333 through the tunneling insulating layer 331 may be facilitated during data erase operation, thereby improving data erase speed.

Specifically, the blocking insulating layer 335 may include at least one of LaMnO₃, LaAlO₃, MgSiO₃, (Ca,Na)(Nb,Ti,Fe)O₃, (Ce,Na,Ca)₂(Ti,Nb)₂O₆, NaNbO₃, SrTiO₃, (Na,La,Ca)(Nb,Ti)O₃, Ca₃(Ti,Al,Zr)₉O₂₀, PbTiO₃, (Ca,Sr)TiO₃, CaTiO₃, Pb(Zr,Ti)O₃, (Ba,Sr)TiO₃, BaTiO₃, KTaO₃, (Bi,La)FeO₃ and Ba(Fe_{1/2}Nb_{1/2})O₃, or may have a multi-layered structure in which each layer is formed of one or more of these materials. The blocking insulating layer 335 may be formed by atomic layer deposition (ALD), chemical vapor deposition (CVD) such as low-pressure CVD (LPCVD), and/or physical vapor deposition (PVD). The blocking insulating layer 335 may be formed to a thickness of about 50 to 500 Å.

The surface of the blocking insulating layer 335 opposite the semiconductor layer 100 may be treated to reduce the trap density of the blocking insulating layer 335. The surface treatment of the blocking insulating layer 335 may be performed using an annealing process and/or a plasma treatment. The annealing process may be performed in the atmosphere of O₂ or an inert gas, such as N₂ or Ar, at a temperature of about 400 to 800° C. The plasma treatment may be performed using an O₂ plasma or an inert gas plasma, such as an N₂ plasma or Ar plasma.

A gate conductive layer 341 may be stacked on the blocking insulating layer 335. The gate conductive layer 341 may be a conductive layer with a Perovskite structure. By forming the gate conductive layer 341 with the same Perovskite structure as the blocking insulating layer 335 on the blocking insulating layer 335, lattice mismatch between the blocking insulating layer 335 and the gate conductive layer 341 can be reduced. As a result, the occurrence of interface defects between the blocking insulating layer 335 and the gate conductive layer 341 can be reduced, and the resistance of the gate conductive layer 341 can be reduced. Specifically, the gate conductive layer 341 may include at least one of CaRuO₃, (Ba,Sr)RuO₃, SrRuO₃, SrlrO₃, LaNiO₃, and (La,Sr)MnO₃, or may have a multi-layered structure in which each layer is formed of one or more of these materials.

The gate conductive layer 341 may be formed by ALD, CVD such as LPCVD, and/or PVD. Also, the gate conductive layer 341 may be formed to a thickness of about 10 to 500 Å.

The surface of the gate conductive layer 341 may be treated to reduce the trap density of the gate conductive layer 341. The surface treatment of the gate conductive layer 341 may be performed using an annealing process and/or a plasma treatment. The annealing process may be performed in the atmosphere of O₂ or an inert gas, such as N₂ or Ar, at a temperature of about 400 to 800° C. The plasma treatment may be performed using an O₂ plasma or an inert gas plasma, such as an N₂ plasma or Ar plasma.

The gate conductive layer 341 with the Perovskite structure may include a material having a larger work function than poly-Si. In this case, a conductive band offset (i.e., a potential barrier to electrons) between the gate conductive layer 341 and the blocking insulating layer 335 is increased, compared with a case where the gate conductive layer 341 is a poly-Si layer. Accordingly, back tunneling of electrons to the charge storage layer 333 through the blocking insulating layer 335 during a data erase operation can be reduced, thereby improving data erase speed.

Although the work function of poly-Si varies according to the type and concentration of impurities, n-type poly-Si has a work function of about 3 eV. In contrast, the gate conductive layer 341 with the Perovskite structure may have a work function of about 4 eV or more. A SrRuO₃ layer, which is an example of the gate conductive layer 341, may have a work function of about 5.0 to 6.3 eV, although its work function varies according to the type of an underlying layer. For example, when the blocking insulating layer 335 is a LaAlO₃ layer and the gate conductive layer 341 is a SrRuO₃ layer, the SrRuO₃ layer may have a work function of about 6.3 eV.

A barrier conductive layer 343 may be formed on the gate conductive layer 341. The barrier conductive layer 343 may reduce/prevent diffusion of hydrogen. The barrier conductive layer 343 may include at least one of metal nitride and metal silicon nitride. For example, the barrier conductive layer 343 may include at least one of TiN, WN, TaN, TiSiN, WSiN, and/or TaSiN, or may have a multi-layered structure in which each layer is formed of one or more of these materials. The barrier conductive layer 343 may have a thickness of about 100 Å. A word line conductive layer 345 may be formed on the barrier conductive layer 343. The word line conductive layer 345 may include at least one of poly-Si, tungsten, tungsten silicide, titanium silicide, and tantalum silicide, or may have a multi-layered structure in which each layer is formed of one or more of these materials. The word line conductive layer 345 may be omitted. Also, the barrier conductive layer 343 may be omitted.

Referring to FIG. 6B, a photoresist pattern is formed on the word line conductive layer 345, and the word line conductive layer 345, the barrier conductive layer 343, the gate conductive layer 341, the blocking insulating layer 335 are patterned using the photoresist pattern. The top surface of the charge storage layer 333 may be exposed on opposite sides of the gate conductive layer 341 and the blocking insulating layer 335. Thereafter, the photoresist pattern is removed.

A hydrogen diffusion blocking spacer insulating layer 350 is formed on the patterned word line conductive layer 345. The hydrogen diffusion blocking spacer insulating layer 350 may include aluminum oxide, silicon nitride, and/or silicon oxide. The hydrogen diffusion blocking spacer insulating layer 350 may be a single layer or a double layer of a lower spacer insulating layer 351 and an upper spacer insulating layer 353. Specifically, the hydrogen diffusion blocking spacer insulating layer 350 may be an aluminum oxide (Al₂O₃) layer. When the hydrogen diffusion blocking spacer insulating layer 350 is a double layer, the upper spacer insulating layer 353 may be an Al₂O₃ layer and the lower spacer insulating layer 351 may be a silicon nitride (Si₃N₄) layer. The upper spacer insulating layer 353 may be a Si₃N₄ layer and the lower spacer insulating layer 351 may be an Al₂O₃ layer.

Referring to FIG. 6C, the hydrogen diffusion blocking spacer insulating layer 350 may be etched back, thereby forming a hydrogen diffusion blocking spacer 350a on a sidewall of the patterned gate conductive layer 341. When the hydrogen diffusion blocking spacer insulating layer 350 includes the lower and upper spacer insulating layers 351 and 353, the hydrogen diffusion blocking spacer 350a may include an L-shaped lower spacer 351a and an upper spacer 353a disposed on the L-shaped lower spacer 351a. Also, the hydrogen diffusion blocking spacer 350a may extend onto a sidewall of the patterned blocking insulating layer 335. As a result, the sidewalls of the gate conductive layer 341 and the blocking insulating layer 335 with the Perovskite structures may be enclosed with the hydrogen diffusion blocking spacer 350a. Furthermore, when the barrier conductive layer 343 is formed, the gate conductive layer 341 and the blocking insulating layer 335 with the Perovskite structures can be encapsulated by the hydrogen diffusion blocking spacer 350a and the barrier conductive layer 343.

The charge storage layer 333 and the tunneling insulating layer 331 may be etched using the hydrogen diffusion blocking spacer 350a and the word line conductive layer 345 as an etch mask. As a result, sidewalls of the patterned charge storage layer 333 and tunneling insulating layer 331 may be aligned with an outer sidewall of the hydrogen diffusion blocking spacer 350a. When the charge storage layer 333 and the tunneling insulating layer 331 are etched using the hydrogen diffusion blocking spacer 350a as a mask as described above, sidewall profiles of the charge storage layer 333 and the tunneling insulating layer 331 may be formed perpendicularly to the substrate 300.

The word line conductive layer 345, the barrier conductive layer 343, the gate conductive layer 341, the blocking insulating layer 335, the charge storage layer 333, the tunneling insulating layer 331, and the hydrogen diffusion blocking spacer 350a constitute a gate structure G.

The substrate 300 having the gate structure G may be hydrogen-annealed. The hydrogen annealing process may be performed in a gas atmosphere containing hydrogen at a temperature of about 500° C. or higher. During the hydrogen annealing process, hydrogen may diffuse into an interface between the tunneling insulating layer 331 and the substrate 300 so as to passivate interface defects. However, the hydrogen diffusion blocking spacer 350 reduces/prevents diffusion of hydrogen during the hydrogen annealing process such that the gate conductive layer 341 and/or the blocking insulating layer 335 may not be exposed to hydrogen. As a result, the decomposition of the gate conductive layer 341 and/or the blocking insulating layer 335 with the Perovskite structures caused by the hydrogen can be reduced/prevented. Furthermore, when the barrier conductive layer 343 is formed, the barrier conductive layer 343 also may reduce/prevent the diffusion of hydrogen, thereby reducing exposure of the gate conductive layer 341 and/or the blocking insulating layer 335 to hydrogen. When the word line conductive layer 345 is formed along with the barrier conductive layer 343, the word line conductive layer 345 may also reduce/prevent the diffusion of hydrogen, so that decomposition of the gate conductive layer 341 and/or the blocking insulating layer 335 with the Perovskite structures can be further reduced. The hydrogen annealing of the substrate 300 having the gate structure G may be performed not only in the current process operation but also in subsequent processes.

N-type or p-type impurities are doped into the semiconductor layer 100 using the gate structure G as a mask, thereby forming impurity regions 301.

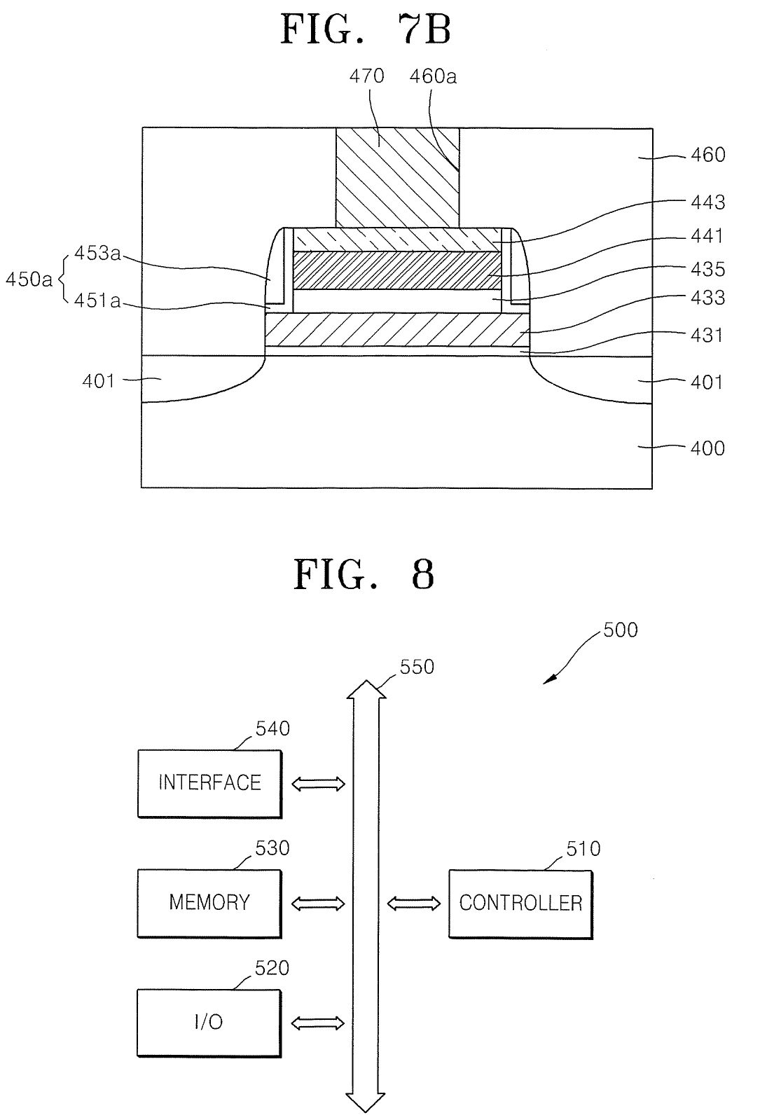

FIGS. 7A and 7B are cross-sectional views illustrating methods of fabricating a nonvolatile memory device according to some embodiments. The methods illustrated in FIGS. 7A and 7B are substantially similar to the methods described with reference to FIGS. 6A through 6C except for the following description.

Referring to FIG. 7A, a tunneling insulating layer 431, a charge storage layer 433, a blocking insulating layer 435, a gate conductive layer 441, and a barrier conductive layer 443 may be stacked on a substrate 400, and the barrier conductive layer 443, the gate conductive layer 441, and the blocking insulating layer 435 may be patterned. Thereafter, a hydrogen diffusion blocking spacer 450a may be formed on sidewalls of the barrier conductive layer 443, the gate conductive layer 441, and the blocking insulating layer 435. The hydrogen diffusion blocking spacer 450a may include an L-shaped lower spacer 451a and an upper spacer 453a disposed on the L-shaped lower spacer 451a. Thereafter, the charge storage layer 433, the tunneling insulating layer 431 may be etched using the hydrogen diffusion blocking spacer 450a and the barrier conductive layer 443 as a mask.

Referring to FIG. 7B, an interlayer insulating layer 460 is formed on the hydrogen diffusion blocking spacer 450 and the barrier conductive layer 442. The interlayer insulating layer 460 may be a silicon oxide layer. A contact hole 460a is formed in the interlayer insulating layer 460 to expose the barrier conductive layer 443. A word line conductive layer is stacked in the contact hole 460a, thereby forming a word line plug 470 contacting the barrier conductive layer 443.

FIG. 8 is a schematic diagram of a system 500 including a nonvolatile memory device according to some embodiments.

Referring to FIG. 8, the system 500 may include a controller 510, an input/output (I/O) device 520, a memory 530, and an interface 540. The system 500 may be a mobile system or a system that transmits or receives data. The mobile system may be a personal digital assistant (PDA), a portable computer, a web tablet, a wireless phone, a mobile phone, a digital music player, or a memory card. The controller 510 may be a microprocessor, a digital signal processor, a microcontroller, or the like. The I/O device 520 may be a keypad, a keyboard, or a display. The memory 530 may store data processed by the controller 510. The memory 530 may include a nonvolatile memory device according to some embodiments. The interface 540 may be a data transmission path between the system 500 and an external apparatus.

The controller 510, the I/O device 520, the memory 530, and the interface 540 may communicate with one another by a bus 550.

According to some embodiments, a blocking insulating layer in a semiconductor memory device is formed of a high-k dielectric material with a Perovskite structure, thereby potentially improving program and erase speeds of the semiconductor memory device. Also, a gate conductive layer with a Perovskite structure is formed on the blocking insulating layer, thereby reducing lattice mismatch between the blocking insulating layer and the gate conductive layer. The gate conductive layer may be formed of a material with a larger work function than poly-Si, and thus back tunneling of electrons to a charge storage layer through the blocking insulating layer during a data erase operation can be reduced, thereby potentially improving erase speed. Furthermore, a hydrogen diffusion blocking spacer is formed on sidewalls of the gate conductive layer and the blocking insulating layer, so that diffusion of hydrogen can be reduced/prevented during a hydrogen annealing process, thereby reducing decomposition of the gate conductive layer and the blocking insulating layer caused by the hydrogen. In addition, the gate conductive layer and the blocking insulating layer may be encapsulated by the hydrogen diffusion blocking spacer and a barrier conductive layer, thereby reducing/preventing the diffusion of hydrogen more effectively.

In the drawings and specification, there have been disclosed typical embodiments and, although specific terms are employed, they are used in a generic and descriptive sense only and not for purposes of limitation, the scope of the invention being set forth in the following claims.

What is claimed is:

1. A nonvolatile memory device comprising:
a tunneling insulating layer on a semiconductor layer;
a charge storage layer on the tunneling insulating layer;
a blocking insulating layer having a Perovskite structure on the charge storage layer; and
a gate conductive layer having a Perovskite structure on the blocking insulating layer.

2. The device of claim 1, further comprising a hydrogen diffusion blocking spacer on a sidewall of the gate conductive layer.

3. The device of claim 2, wherein the hydrogen diffusion blocking spacer extends onto a sidewall of the blocking insulating layer.

4. The device of claim 2, wherein the hydrogen diffusion blocking spacer comprises aluminium oxide, silicon nitride, and/or silicon oxide.

5. The device of claim 4, wherein the hydrogen diffusion blocking spacer comprises a single layer of an aluminum oxide layer, a double layer of an aluminum oxide layer and a silicon nitride layer, and/or a double layer of a silicon nitride layer and a silicon oxide layer.

6. The device of claim 1, further comprising a barrier conductive layer on the gate conductive layer.

7. The device of claim 6, wherein the barrier conductive layer comprises TiN, WN, TaN, TiSiN, WSiN, and/or TaSiN.

8. The device of claim 6, further comprising a word line conductive layer on and electrically connected to the barrier conductive layer.

9. The device of claim 1, wherein the gate conductive layer comprises CaRuO₃, (Ba,Sr)RuO₃, SrRuO₃, SrlrO₃, LaNiO₃, and/or (La,Sr)MnO₃.

10. The device of claim 1, wherein the gate conductive layer comprises a material having a larger work function than polysilicon (poly-Si).

11. The device of claim 10, wherein the gate conductive layer comprises SrRuO₃.

12. The device of claim 1, wherein the blocking insulating layer comprises LaMnO₃, LaAlO₃, MgSiO₃, (Ca,Na)(Nb,Ti,Fe)O₃, (Ce,Na,Ca)₂(Ti,Nb)₂O₆, NaNbO₃, SrTiO₃, (Na,La,Ca)(Nb,Ti)O₃, Ca₃(Ti,Al,Zr)₉O₂₀, PbTiO₃, (Ca,Sr)TiO₃, CaTiO₃, Pb(Zr,Ti)O₃, (Ba,Sr)TiO₃, BaTiO₃, KTaO₃, (Bi,La)FeO₃ and/or Ba(Fe_{1/2}Nb_{1/2})O₃.

13. The device of claim 2, wherein the hydrogen diffusion blocking spacer is on the charge storage layer.

14. A method of fabricating a nonvolatile semiconductor memory device, comprising:
forming a tunneling insulating layer on a semiconductor layer;
forming a charge storage layer on the tunneling insulating layer;
forming a blocking insulating layer having a Perovskite structure on the charge storage layer; and
forming a gate conductive layer having a Perovskite structure on the blocking insulating layer.

15. The method of claim 14, further comprising forming a hydrogen diffusion blocking spacer on a sidewall of the gate conductive layer.

16. The method of claim 15, wherein the hydrogen diffusion blocking spacer extends onto a sidewall of the blocking insulating layer.

17. The method of claim 14, wherein the gate conductive layer comprises CaRuO₃, (Ba,Sr)RuO₃, SrRuO₃, SrlrO₃, LaNiO₃, and/or (La,Sr)MnO₃.

18. The method of claim 14, wherein the gate conductive layer comprises a material having a larger work function than polysilicon (poly-Si).

19. The method of claim 18, wherein the gate conductive layer comprises SrRuO₃.

20. The method of claim 14, wherein the blocking insulating layer comprises LaMnO₃, LaAlO₃, MgSiO₃, (Ca,Na)(Nb,Ti,Fe)O₃, (Ce,Na,Ca)₂(Ti,Nb)₂O₆, NaNbO₃, SrTiO₃, (Na,La,Ca)(Nb,Ti)O₃, Ca₃(Ti,Al,Zr)₉O₂₀, PbTiO₃, (Ca,Sr)TiO₃, CaTiO₃, Pb(Zr,Ti)O₃, (Ba,Sr)TiO₃, BaTiO₃, KTaO₃, (Bi,La)FeO₃ and/or Ba(Fe_{1/2}Nb_{1/2})O₃.
